(19) United States
(12) Patent Application Publication
(10) Pub. No.: US 2009/0096081 A1
(43) Pub. Date: Apr. 16, 2009

(54) Semiconductor device

(75) Inventor: Shin Soyano, Shiojiri-shi (JP)

Correspondence Address: KANESAKA BERNER AND PARTNERS LLP, 1700 DIAGONAL RD, SUITE 310, ALEXANDRIA, VA, 22314-2848, US

(73) Assignee: FUJI ELECTRIC DEVICE TECHNOLOGY CO., LTD., Tokyo (JP)

(21) Appl. No.: 12/232,839

(22) Filed: Sep. 25, 2008

(30) Foreign Application Priority Data
Oct. 15, 2007 (JP) 2007-267473

(51) Int. Cl. H01L 23/04

(52) U.S. Cl. 257/698; 257/E23.181

(57) ABSTRACT

A semiconductor device includes a substrate, at least one semiconductor element mounted on the substrate, a resin housing for housing the semiconductor element, the resin housing having a cover thereon, at least one pin provided and standing in the resin housing, and at least one printed substrate disposed inside the resin housing or outside the resin housing. The printed substrate and the cover of the resin housing are positioned by the pin.

### BACKGROUND OF THE INVENTION AND RELATED ART STATEMENT

The present invention relates generally to a semiconductor device and in particular to a semiconductor device that packages semiconductor elements.

Semiconductor devices (general-purpose modules) having power semiconductor elements are used in inverters, uninterruptible power supplies, machine tools, industrial robots and the like, the power semiconductor being independent of their main bodies.

These semiconductor devices generally have a structure encapsulating a plurality of elements in a resin housing. Recently, IPMs (intelligent power modules), which include a control board(s) for driving the elements in a semiconductor device, are becoming the main stream.

The control board needs accurate positioning in the semiconductor device for improving an assembly work, which is required for a miniaturization of the semiconductor device. Accordingly, a semiconductor device has been disclosed recently (for example, Patent Document 1: Japanese Unexamined Patent Application Publication No. 2007-115987) in which a positioning pin is provided in the encapsulating housing and the control board is fit to the pin to accurately position the control board. FIG. 4 schematically shows this semiconductor device.

FIG. 4 illustrates a construction of an essential part of the semiconductor device.

Referring to FIG. 4, the semiconductor device 100 comprises a plurality of insulated substrates 102 mounted on a base plate 101 and semiconductor elements 103 mounted on the respective insulated substrates 102.

External frames 104a and 104b of the housing are fixed to the upper periphery of the base plate 101. An internal frame 104c of the housing is fixed on the central region of the base plate 101. Lead frames 105a and 105b fixed to the external frame 104a and the internal frame 104c are electrically connected to electrodes of the semiconductor elements 103 through wires 106a and 106b.

In the semiconductor device 100, a control board 107 is positioned by means of pins 108 provided on the external frames 104a and 104b and disposed over the semiconductor elements 103 through base parts 109.

The semiconductor device 100 shown in FIG. 4, however, is only provided with the positioning pins 108 dedicated to the control board 107, on the external frames 104a and 104b of the semiconductor device 100.

This construction of a semiconductor device has a problem in the case where a plurality of control boards having smaller area than that of the control board 107 is to be arranged in the semiconductor device and in the case where a resin housing cover is arranged together with the plurality of control boards, since they cannot get positioned together.

In addition, the structure having the positioning pins 108 on the external frames 104a and 104b has a problem that a compact construction of a semiconductor device cannot be achieved.

The present invention has been made in view of the problems shown above. An object of the invention is to provide a semiconductor device that allows simultaneous positioning of a plurality of control boards having different areas together and simultaneous positioning of a plurality of control boards and a resin housing cover together.

Another object of the invention is to provide a semiconductor device that can be easily assembled and has a compact configuration.

Further objects and advantages of the invention will be apparent from the following description of the invention.

### SUMMARY OF THE INVENTION

To solve the above problems, a semiconductor device provided by the present invention comprises at least one semiconductor element mounted on a substrate, a resin housing containing the semiconductor element, at least one pin provided to stand at a place in the resin housing, and at least one printed substrate disposed inside the resin housing or outside the resin housing, wherein the printed substrate and a cover part of the resin housing are positioned by the pin.

In a semiconductor device according to the invention, at least one semiconductor element is mounted on the substrate, the semiconductor element is contained in the resin housing, and at least one pin is provided to stand at a place within the resin housing. Further, at least one printed substrate is disposed inside the resin housing or outside the resin housing. The printed substrate and a cover part of the resin housing that are disposed at predetermined locations are positioned by means of the pin.

A semiconductor device according to the invention allows simultaneous positioning of a plurality of control boards having different areas together and simultaneous positioning of a plurality of control boards and the resin housing cover together. Further, the invention provides a semiconductor device that can be easily assembled and has a compact configuration.

### BRIEF DESCRIPTION OF THE DRAWINGS

FIG. 1 is a schematic sectional view of an essential part of a semiconductor device according to an embodiment of the invention;

FIG. 2 is a schematic sectional view of a variation example of a semiconductor device of the invention;

FIG. 3 is a schematic sectional view illustrating an assembling procedure of the semiconductor device; and

FIG. 4 illustrates construction of an essential part of a conventional semiconductor device.

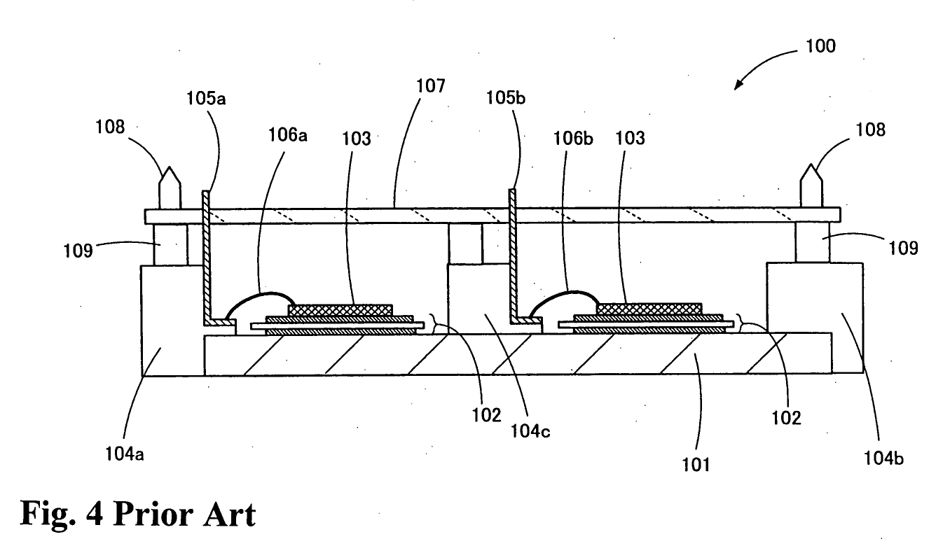

### DETAILED DESCRIPTION OF PREFERRED EMBODIMENTS

Some preferred embodiments of the invention will be described in detail with reference to the accompanying drawings.

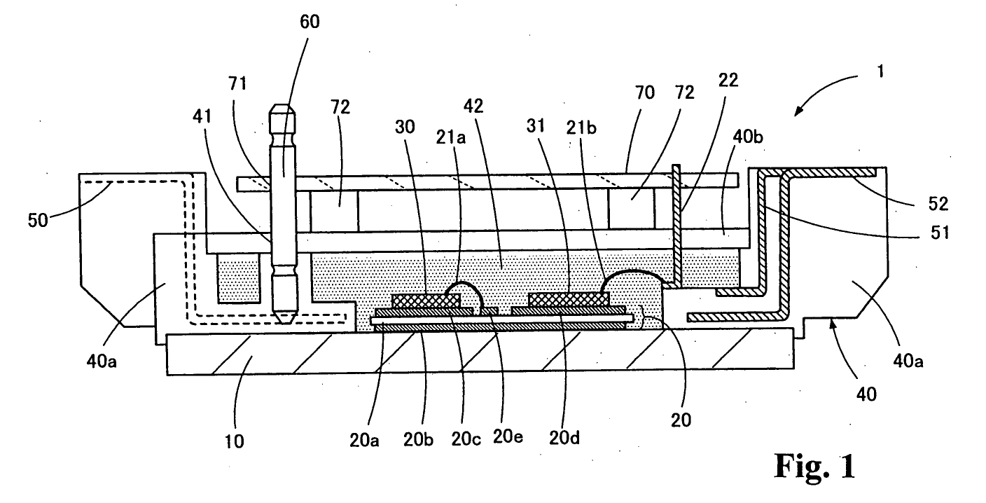

FIG. 1 is a schematic sectional view of an essential part of a semiconductor device according to an embodiment of the invention.

The semiconductor device 1 shown in FIG. 1 has a base body of a metal base plate 10 with a thickness of several millimeters and an insulated substrate 20 bonded to the metal base plate 10 through a lead-free solder layer (not shown in the figure) of a tin (Sn)-silver (Ag) system. A plurality of semiconductor elements 30, 31 is mounted on the insulated substrate 20. The semiconductor device 1, packaging the semiconductor elements 30, 31 and other components in a resin housing 40, functions as a general-purpose IGBT module.

The insulated substrate 20 includes an insulator plate 20a, a sheet of metal foil 20b formed by a DCB (direct copper bonding) method on the lower surface of the insulator plate 20a, and plural sheets of metal foils 20c, 20d, 20e formed by the DCB method on the upper surface of the insulator plate 20a. The metal foils 20c, 20d, and 20e each forms a circuit pattern, which is different from the others on the insulator plate 20a.

One or more semiconductor elements 30, 31 are mounted on the metal foils 20c, 20d through a solder layer (not shown in the figure) with the back surface side of the element (a collector electrode side, for example) bonded to the metal foil.

On the principal plane opposite to the bonding surface (the back surface side), that is, the upper surface of the semiconductor elements 30, 31, control electrodes and emitter electrodes (not shown) are provided. The control electrode of the semiconductor element 30 is electrically connected to the metal foil 20e through a metal wire 21a. The metal foil 20e is connected to a circuit pattern (a control circuit, for example) not shown in the figure. The control electrode of the semiconductor element 31 is connected through a metal wire 21b to a pin terminal (a control terminal) 22 fixed on the resin housing 40.

The insulator plate 20a is composed of sintered ceramic of alumina (Al₂O₃), for example, and the metal foils 20b, 20c, and 20d are composed of a metallic material having copper as a main composition.

The semiconductor elements 30, 31 are vertical power semiconductor elements, for example, IGBTs, each having a principal electrode (an emitter electrode, for example) and a control electrode (a gate electrode) on the upper principal plane of the element, and another principal electrode (a collector electrode, for example) on the lower principal plane. The semiconductor elements 30, 31 are not limited to the IGBTs, but can be power MOSFETs (metal oxide semiconductor field effect transistors) or FWDs (free-wheeling diodes).

Although not shown in FIG. 1, plural sheets of metal foils in addition to the metal foils 20c and 20d are patterned on the insulator plate 20a, and some electrode terminals are arranged.

The semiconductor device 1 comprises an external frame 40a composing the resin housing 40, the external frame being fixed on the upper periphery of the metal base plate 10 and made of PPS (Polyphenylene Sulfide), for example. In the external frame 40a, external connection terminals 50, 51, and 52 connecting to the principal electrodes of the semiconductor elements 30 and 31 are molded (insert molded).

The external connection terminals 50, 51, and 52 are composed of a material having copper as a main component. In the semiconductor device 1 also provided are a plurality of control terminals (pin terminals, for example) electrically connecting to the control electrodes of the semiconductor elements 30 and 31.

The semiconductor device 1 comprises at least one positioning pin 60 (with a cylindrical shape) standing vertically in the resin housing 40. An end of the pin is fixed (inserted) in the external frame 40a. A cover part 40b composing the resin housing 40 is disposed over the semiconductor elements 30 and 31, the cover part being fitted to the external frame 40a. The pin 60 is mainly composed of a metal or a resin. When a resin is used, electric insulation is ensured even if the metal wires 21a, 21b, electrodes, or other components arranged in the resin housing 40 become in contact with the pin 60. A cross sectional configuration in the transverse direction (the cross section cut in the left and right direction in FIG. 1) can be a triangle, a square, or a hexagon as well as a circular shape.

The pin 60 passes through a through-hole 41 formed in the cover part 40b and is extending upward from the cover part 40b. The pin 60 further passes through a through-hole 71 formed in a printed substrate 70 (a control board, for example) disposed over the cover part 40b. The upper end of the pin extends upwards from the printed substrate 70.

The pin terminal 22 is disposed standing vertically through the cover part 40b and connected electrically with a solder to a circuit pattern (not shown) formed on the principal plane of the printed substrate 70.

A clearance can be formed without direct contact between the outer surface of the pin 60 passing through the through-holes 41 and 71, and the inner surfaces of these through-holes in the cover part 40b and the printed substrate 70.

A position of disposing the pin 60 is not limited to the position indicated in FIG. 1 but can be at any place in the resin housing 40, that is, in the space enclosed by the metal base plate 10, external frame 40a, and the cover part 40b.

This space enclosed by the external frame 40a, the cover part 40b, and the metal base plate 10 is filled with gel 42 for the purpose of protecting the semiconductor elements 31 and 31, the metal wires 21a and 21b, and other components. A material for the gel 42 can be composed of mainly silicone, for example.

The printed substrate 70 in the semiconductor device 1 is mounted opposing the cover part 40b and supported by support rods (base parts) 72 as described previously. The upper end of the pin terminal 22 is electrically connected with a solder to a plurality of circuit patterns (not shown) formed on the principal plane of the printed substrate 70. In the printed substrate 70 installed are an IC circuit(s), a capacitor(s), a resistor(s), and other circuit elements.

The semiconductor device 1 can have a so-called metal baseless structure in which the metal base plate 10 is eliminated and the insulated substrate 20 functions as a base body of the semiconductor device 1, in order to achieve small size and light weight of the semiconductor device.

The semiconductor device 1 shown in FIG. 1 has one printed substrate 70 disposed above and opposing the cover part 40b. The number of printed substrate disposed above the cover part is not limited to only one, but one or more printed substrates can be mounted in the semiconductor device 1.

The location for disposing the printed substrates is not limited to the place over the cover 40b of the semiconductor device 1, but one or more printed substrates can be disposed within the space enclosed by the metal base plate 10, the external frame 40a, and the cover part 40b.

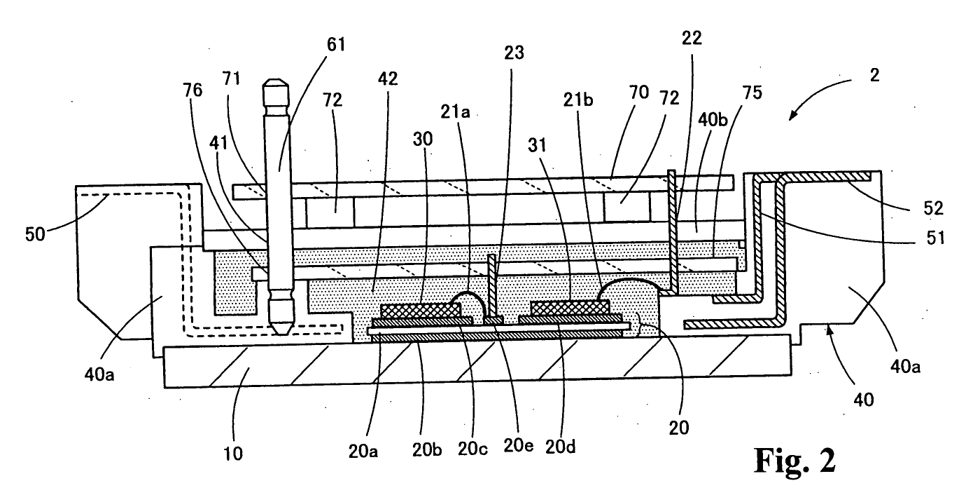

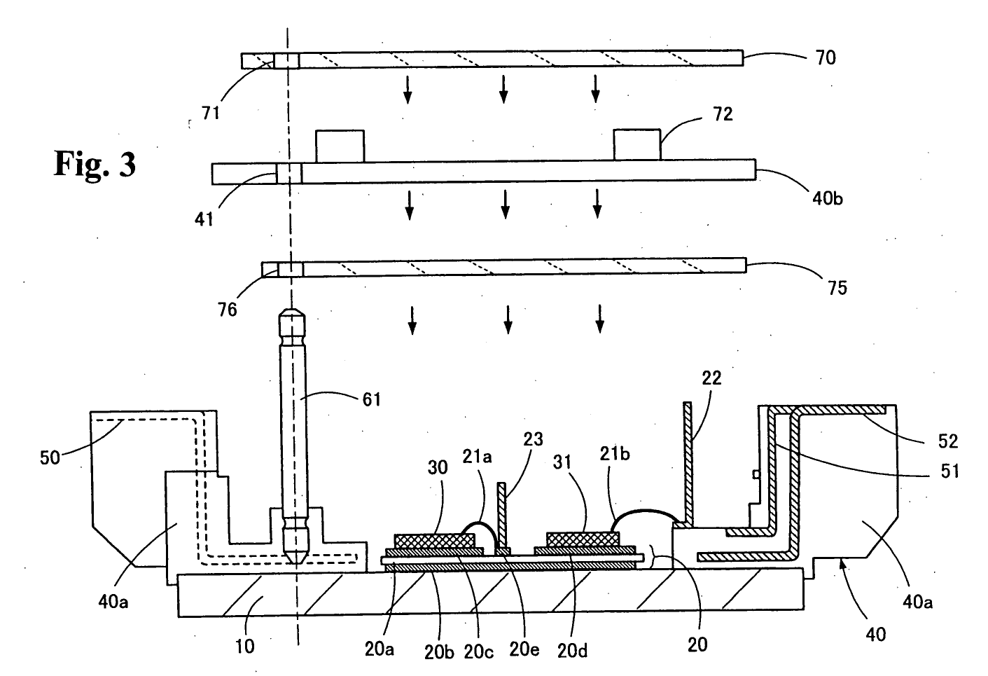

A variation example from the semiconductor device 1 of FIG. 1 is described referring to FIG. 2. In FIG. 2 and FIG. 3, the same members as in FIG. 1 are given the same symbols, and detailed descriptions thereon are omitted.

FIG. 2 is a schematic sectional view of an essential part of the variation example of semiconductor device of the invention.

Referring to FIG. 2, a semiconductor device 2 comprises a printed substrate 75 disposed in the space enclosed by a metal base plate 10, an external frames 40a, and a cover part 40b. In the semiconductor device 2, a pin terminal 23 is provided standing from a metal foil 20e in a resin housing 40.

The pin terminal 23 is connected and fixed to the metal foil 20e disposed on an insulator plate 20a. A pin terminal 22 is fixed to the resin housing 40 as in the semiconductor device 1. Control electrodes of the semiconductor elements 30 and 31 are electrically connected to the pin terminals 23 and 22 through metal wires 21a and 21b.

The upper end of the pin terminal 23 passes through the printed substrate 75 and electrically connects with a solder to a circuit pattern formed on the principal plane of the printed substrate 75. The pin terminal 22 passes through the printed substrate 75 and further through the printed substrate 70, and electrically connects with a solder to a circuit pattern formed on the principal plane of the printed substrate 70.

The pin terminal 22 can be electrically connected also to the circuit pattern formed on the printed substrate 75 as necessary.

The semiconductor device 2 is provided with at least one positioning pin 61 standing vertically in the resin housing 40. An end of the pin 61 is fixed (inserted) in the external frame 40a. The printed substrate 75 (a control board, for example) is disposed over the semiconductor elements 30 and 31. Over the printed substrate 75, the cover part 40b is disposed to be fit to the external frame 40a.

The pin 61 passes through a through-hole 76 formed in the printed substrate 75 and the through-hole 41 formed in the cover part 40b. Further, the pin 61 extends upward from the cover part 40b. And the pin 61 further passes through a through-hole 71 formed in the printed substrate 70 (a control board, for example) disposed above the cover part 40b, and the upper end of the pin 61 is extending upward from the printed substrate 70.

A clearance can be formed without a direct contact between the outer surface of the pin 61 passing through the through-holes 41, 71, and 76, and the inner surfaces of the through-holes in the cover part 40b and the printed substrates 70 and 75.

A position of disposing the pin 61 is not limited to the position indicated in FIG. 2, but it can be at any place in the resin housing 40, that is, in the space enclosed by the metal base plate 10, external frames 40a, and the cover part 40b.

Incorporation of a temperature sensor circuit, overvoltage and overcurrent protection circuits, and the like in the principal plane of the printed substrate 75 achieves an IPM with a small and thin size.

Thus, at least one sheet of printed substrate can be provided in the space enclosed by the metal base plate 10, the external frames 40a, and the cover part 40b.

In this construction, in which the pin 61 determines the positions of the printed substrates 70 and 75, precise positioning is attained between the pin terminals 22, 23, and the through-holes formed in the printed substrates 70, 75. Moreover, assembling of the device is facilitated because the pin terminals 22 and 23 can be easily passed through the through-holes in the printed substrates 70 and 75.

In recent semiconductor devices with enhanced integration, the pin terminals 22 and 23 need to be thin wires. The device of the invention, exhibiting facilitated assembly, prevents securely the pin terminals from bend and damage that might occur in the assembling process.

Next, a method of simultaneous positioning of the plurality of printed substrates 70, 75, and the cover part 40b together is described in an example of the semiconductor device 2 shown in FIG. 2.

FIG. 3 is a schematic sectional view of an essential part of a semiconductor device illustrating the method of assembling the semiconductor device.

Referring to FIG. 3, the printed substrates 70, 75, and the cover part 40b are arranged over the semiconductor device 2.

Then, positioning is conducted between the pin 61 and the through-hole 76 formed in the printed substrate 75, and the pin 61 is passed through the through-hole 76. Keeping the inserted state, the printed substrate 75 is moved downwards and located at a predetermined position over the semiconductor elements 30 and 31 as shown in FIG. 2.

Subsequently, positioning is conducted between the pin 61 and the through-hole 41 formed in the cover part 40b, and the pin 61 is passed through the through-hole 41. Keeping the inserted state, the cover part 40b is moved downwards and located at a predetermined position over the printed substrate 75. Thus, the cover part 40b is fitted to the external frame 40a as shown in FIG. 2.

Then, positioning is conducted between the pin 61 and the through-hole 71 formed in the printed substrate 70, and the pin 61 is passed through the through-hole 71. Keeping the inserted state, the printed substrate 70 is moved downwards and located at a predetermined position over the cover part 40b via the support rods 72 as shown in FIG. 2.

After fitting the cover part 40b to the external frame 40a, the space enclosed by the metal base plate 10, the cover part 40b, and the external frames 40a can be filled with gel 42.

As described above, the semiconductor devices 1, 2 comprise at least one semiconductor element 30, 31 mounted on the insulated substrate 20, the semiconductor elements 30, 31 being contained in the resin housing 40, and at least one pin 60, 61 standing at a place in the resin housing 40.

At least one printed substrate 70, 75 is disposed inside or outside of the resin housing 40, or inside and outside of the resin housing 40.

The printed substrates 70, 75 and the cover part 40b of the resin housing 40 are positioned by a common pin 60 or 61.

In the semiconductor devices 1, 2, all of the cover part 40b, the printed substrate 70 and the printed substrate 75 are easily positioned together with reference to the common pin 60 or 61. Since provision of only a common pin 60 or 61 is sufficient, the semiconductor device can be made at a reduced cost.

Because positioning of the cover part 40b, the printed substrate 70 and the printed substrate 75 is conducted with reference to one pin 60 or 61, these components can be positioned with enhanced precision.

When the external connection terminals 50, 51, and 52 are insert molded in the external frame 40a, a place for locating the pin 60, 61 is limited in the external frame 40a. However, in an embodiment of the invention, the pin 60 or 61 can be disposed at any place in the resin housing 40. Consequently, freedom of arrangement of the pin 60, 61 is increased significantly. Thus, design margin is expanded, achieving a small and thin semiconductor device.

The disclosure of Japanese Patent Application No. 2007-267473 filed on Oct. 15, 2007 is incorporated as a reference.

While the invention has been explained with reference to the specific embodiments of the invention, the explanation is illustrative and the invention is limited only by the appended claims.

What is claimed is:

1. A semiconductor device, comprising:
a substrate;
at least one semiconductor element mounted on the substrate;
a resin housing for housing the semiconductor element, said resin housing having a cover thereon;
at least one pin standing in the resin housing; and
at least one printed substrate disposed inside the resin housing or outside the resin housing, wherein the printed substrate and the cover of the resin housing are positioned by the pin.

2. The semiconductor device according to claim 1, wherein at least one printed substrate is disposed inside the resin housing, and at least one printed substrate is disposed outside the resin housing.

3. The semiconductor device according to claim 1, wherein the printed substrate is a control board of the semiconductor device.

4. The semiconductor device according to claim 1, wherein a major material of the pin is a metal or a resin.

5. The semiconductor device according to claim 1, wherein the pin has a configuration of a cross-section in a transverse direction selected from the group consisting of circle, a triangle, a square, and a hexagon.

6. The semiconductor device according to claim 1, further comprising a pin terminal disposed in the resin housing and standing vertically through the cover, and a metal wire for connecting the semiconductor element and the pin terminal, the pin terminal being connected electrically with a solder to a circuit pattern formed on the printed substrate.

7. The semiconductor device according to claim 1, further comprising a gel provided to fill a space enclosed by the resin housing, the cover, and the substrate for protecting the at least one semiconductor element.
